(19) United States
(12) Patent Application Publication
(10) Pub. No.: US 2011/0157993 A1
(43) Pub. Date: Jun. 30, 2011

(54) SEMICONDUCTOR MEMORY DEVICE AND READ METHOD THEREOF

(75) Inventor: Sang Hwan KIM, Seoul (KR)

(73) Assignee: HYNIX SEMICONDUCTOR INC., Icheon-si (KR)

(21) Appl. No.: 12/982,783

(22) Filed: Dec. 30, 2010

(30) Foreign Application Priority Data
Dec. 31, 2009 (KR) 10-2009-0135628

(51) Int. Cl. G11C 16/04

(52) U.S. Cl. 365/185.18; 365/189.05

(57) ABSTRACT

A read method using a semiconductor memory device includes reading data of a cell adjacent to a cell to be read and storing the data in a first latch of a first page buffer, sending the data, stored in the first latch, to a second latch of a second page buffer adjacent to the first page buffer, setting a read voltage of the cell to be read according to a value of the data stored in the first and second latches, and reading data of the cell to be read using the set read voltage.

### CROSS-REFERENCE TO RELATED APPLICATION

Priority is claimed to Korean patent application number 10-2009-0135628 filed on Dec. 31, 2009, the entire disclosure of which is incorporated by reference herein.

### BACKGROUND

Exemplary embodiments relate to a semiconductor memory device and a read method thereof.

A nonvolatile memory device includes a memory cell array in which data is stored. The memory cell array includes a plurality of strings. Each of the strings includes a drain select transistor, a source select transistor, and a plurality of memory cells coupled in series between the drain select transistor and the source select transistor.

The strings are classified as an even string or an odd string according to the sequence in which a corresponding string is arranged. That is, the even strings and the odd strings are alternately arranged, and the strings are coupled to respective bit lines.

With an increase of the degree of integration of semiconductor devices, the strings are classified into at least two groups and a program operation is performed on the two groups separately in order to prevent taxing voltage supplied to the bit lines during the program operation.

For example, after a program operation, or a store operation, is performed on memory cells included in the odd strings, a program operation may be performed on memory cells included in the even strings.

Meanwhile, the memory cells of the odd strings on which the program operation has been performed may be subjected to interference when the program operation is performed on the memory cells of the even strings adjacent to the memory cells of the odd strings. Consequently, threshold voltages of the memory cells of the odd strings may rise.

Accordingly, erroneous data may be read because the threshold voltage of a cell to be read may rise because of interference occurring when a program operation is performed on neighboring cells.

### BRIEF SUMMARY

Exemplary embodiments relate to a semiconductor memory device and a read method thereof, in which a read operation for a cell is performed by changing a read voltage according to whether cells adjacent to the cell to be read have been programmed when data is read from a cell.

A read method using a semiconductor memory device according to an aspect of the present disclosure includes reading a first data of a cell adjacent to a cell to be read and storing the first data in a first latch of a first page buffer, sending the first data, stored in the first latch, to a second latch of a second page buffer adjacent to the first page buffer, setting a read voltage of the cell to be read according to a value of the data stored in the first and second latches, and reading a second data of the cell to be read using the set read voltage.

The read method further includes, after storing the data in the first and second latches, if only one of the data stored in the first and second latches is changed, raising a level of the read voltage by a first level, and if both data stored in the first and second latches is changed, raising the level of the read voltage by a second level higher than the first level.

A semiconductor memory device according to an aspect of the present disclosure includes page buffers, each allocated to a pair of bit lines, and comprising first, second, and third latches. Transmission circuits are coupled between adjacent page buffers, and a determination unit is configured to determine whether read cells are in a program state or an erase state according to the data stored in the first to third latches.

A semiconductor memory device according to another aspect of the present disclosure includes first to fourth strings, first to fourth bit lines respectively coupled to the first to fourth strings, a first bit line selection unit configured to select any one of the first and second bit lines, a second bit line selection unit configured to select any one of the third and fourth bit lines. Additionally, first and second page buffers are each configured to comprise first, second, and third latches and to store read data of a memory cell in a latch of any one of the first to third latches through the selected bit line, a transmission circuit configured to send the data of the first latch of the second page buffer to the third latch of the first page buffer, and a determination unit configured to determine whether read cells have been programmed on the basis of the data stored in the first to third latches of each of the first and second page buffers. The determination unit determines the data of each of the first to third latches.

### BRIEF DESCRIPTION OF THE DRAWINGS

FIG. 1 is a schematic bloc diagram of a semiconductor memory according to an embodiment of the invention;

FIG. 2 is a detailed circuit diagram of the semiconductor memory device according to an embodiment of the invention;

FIG. 3 is a flowchart illustrating a read method for the semiconductor memory device according to an embodiment of the invention; and

FIG. 4 is a diagram illustrating read voltage according to a shift of threshold voltages.

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the embodiments of the disclosure.

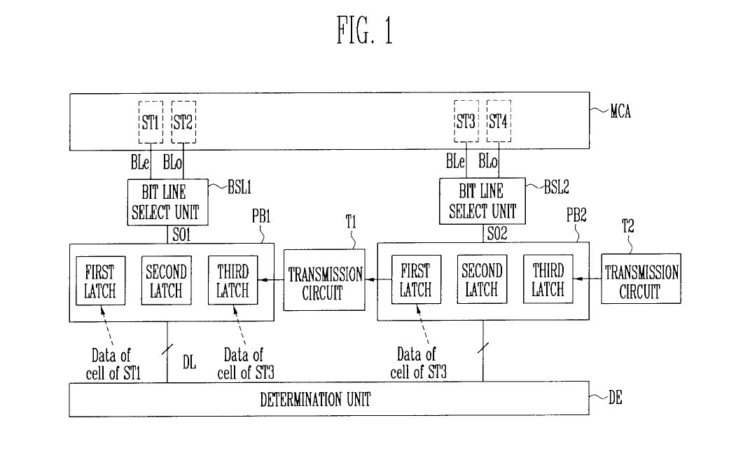

FIG. 1 is a schematic bloc diagram of a semiconductor memory according to this disclosure.

The semiconductor memory device includes a memory cell array MCA including first to fourth strings ST1 to ST4 each having a plurality of memory cells, bit line select circuits BSL1 and BSL2 for selecting bit lines, page buffers PB1 and PB2 for inputting and outputting data, and a determination unit DE for determining data.

Each of the first to fourth strings ST1 to ST4 of the memory cell array MCA is coupled to an even or odd bit line BLe or BLo. Each of the bit line selection units BSL1 and BSL2 selects one of the even and odd bit lines BLe and BLo. Each of the page buffers PB1 and PB2 includes first to third latches in which data will be stored.

The determination unit DE determines whether cells adjacent to a cell to be read have been programmed on the basis of data stored in the first to third latches.

A read method for the semiconductor memory device constructed as above is described below. For example, a case where a cell to be read is included in the second string ST2 is described below.

Data of cells adjacent to the cell to be read in the second string ST2 (that is, data in cells included in the first and third strings ST1 and ST3) are read and stored in the first latches of the page buffer PB1 and PB2. That is, data of a cell included in the first string ST1, from among cells to be read, is stored in the first latch of the first page buffer PB1, and data of a cell included in the third string ST3, from among the cells to be read, is stored in the first latch of the second page buffer PB2. In other words, the cell to be read and the neighboring cells are read, and data read from the neighboring cells is stored in the first latches each of the first and second page buffers PB1 and PB2.

Next, the data stored in the first latch of the page buffer is transferred to the third latch of a neighboring page buffer through a transmission circuit T1 or T2. That is, the data stored in the first latch of the second page buffer PB2 is transferred to the third latch of the first page buffer PB1.

Accordingly, the data of the cell included in the first string ST1 is stored in the first latch of the first page buffer PB1, and the data of the cell included in the third string ST3 is stored in the third latch of the first page buffer PB1.

The determination unit DE determines whether cells adjacent to selected cells have been programmed on the basis of the data stored in the first and third latches and controls a read voltage of the cell to be read on the basis of a result of the determination.

The above is described in more detail below.

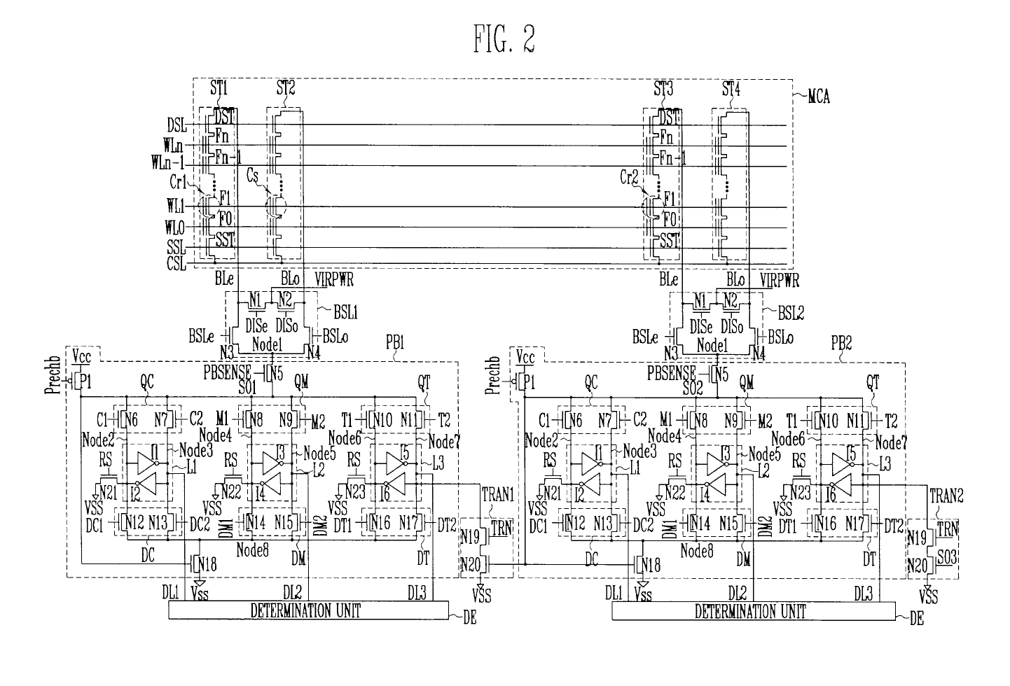

FIG. 2 is a detailed circuit diagram of the semiconductor memory device according to an embodiment of the invention.

The memory cell array MCA includes the strings ST1 to ST4. Each of the strings ST1 to ST4 includes a drain select transistor DST, a source select transistor SST, and a plurality of memory cells F0 to Fn coupled in series between the drain and source select transistors DST and SST. The gates of the drain select transistors DST included in the strings ST1 to ST4 are coupled to form a drain select line DSL, and the gates of the source select transistors SST included in the strings ST1 to ST4 are coupled to form a source select line SSL. The gates of the memory cells F0 to Fn included in the strings ST1 to ST4 are coupled to form a plurality of word lines WL0 to WLn. The sources of the source select transistors SST are coupled to a common source line CSL, and the drain of the drain select transistor DST of each string is coupled to the even or odd bit line BLe or BLo.

The bit line select circuits BSL1 and BSL2 have the same configuration, and the page buffers PB1 and PB2 also have the same configuration. Accordingly, only the first bit line select circuit BSL1 and the first page buffer PB1 are described in order to avoid redundancy.

The first bit line select circuit BSL1 includes first and second switching elements N1 and N2 coupled in series between the even bit line BLe and the odd bit line BLo, a third switching element N3 coupled between the even bit line BLe and a first node Node1, and a fourth switching element N4 coupled between the odd bit line BLO and the first node Node1. The first to fourth switching elements N1 to N4 may be implemented using an NMOS transistor.

Virtual voltage VIRPWR is supplied between the first switching element N1 and the second switching element N2. The first switching element N1 is operated in response to an even discharge signal DISe, and so virtual voltage VIRPWR is supplied to the even bit line BLe. The second switching element N2 is operated in response to an odd discharge signal DISo, and so the virtual voltage VIRPWR is supplied to the odd bit line BLO. The third switching element N3 is operated in response to an even select signal BSLe. When the third switching element N3 is turned on, the even bit line BLe is selected. The fourth switching element N4 is operated in response to an odd select signal BSLo. When the fourth switching element N4 is turned on, the odd bit line BLo is selected.

The first page buffer PB1 includes a precharge circuit P1, a sense circuit N5, first to third transfer circuits QC, QM, and QT, first to third latches L1, L2 and L3, reset circuits N21 to N23, first to third setup circuits DC, DM, and DT, and a discharge circuit N18.

The precharge circuit P1 is operated in response to a precharge signal PRECHb and is implemented using a PMOS transistor. When the precharge signal PRECHb is enabled, a sense node SO1 is precharged. The sense circuit N5 is operated in response to a sense signal PBSENSE and is implemented using an NMOS transistor. When the sense signal PBSENSE is enabled, the bit line BLo or BLe selected by the first bit line select circuit BSL1 is coupled to the sense node SO1.

The first transfer circuit QC, the first latch L1, and the first setup circuit DC are coupled in series between the sense node SO1 and an eighth node Node8. The second transfer circuit QM, the second latch L2, and second setup circuit DM are coupled in series between the sense node SO1 and the eighth node Node8. The third transfer circuit QT, the third latch L3, and the third setup circuit DT are coupled in series between the sense node SO1 and the eighth node Node8.

The first transfer circuit QC includes sixth and seventh switching elements N6 and N7, which may be NMOS transistors. When the sixth switching element N6 is turned on, a second node Node2 is coupled to the sense node SO1. When the seventh switching element N7 is turned on, a third node Node3 is coupled to the sense node SO1.

The second transfer circuit QM includes eighth and ninth switching elements N8 and N9, which may be NMOS transistors. When the eighth switching element N8 is turned on, a fourth node Node4 is coupled to the sense node SO1. When the ninth switching element N9 is turned on, a fifth node Node5 is coupled to the sense node SO1.

The third transfer circuit QT includes tenth and eleventh switching elements N10 and N11, which may be NMOS transistors. When the tenth switching element N10 is turned on, a sixth node Node6 is coupled to the sense node SOL When the eleventh switching element N11 is turned on, a seventh node Node7 is coupled to the sense node SO1.

The first latch L1 includes inverters I1 and I2 forming a pair, the second latch L2 includes inverters I3 and I4 forming a pair, and the third latch L3 includes inverters I5 and I6 forming a pair.

The first setup circuit DC includes twelfth and thirteenth switching elements N12 and N13, which may be NMOS transistors, and performs an operation of setting up the first latch L1. The second setup circuit DM includes fourteenth and fifteenth switching elements N14 and N15, which may be NMOS transistors, and performs an operation of setting up the second latch L2. The third setup circuit DT includes sixteenth and seventeenth switching elements N16 and N17, which may be NMOS transistors, and performs an operation of setting up the third latch L3.

The reset circuits N21 to N23 reset the first to third latches L1 to L3 in response to a reset signal RS.

The discharge circuit N18 is formed of an NMOS transistor and coupled between the eighth node Node8 and a ground terminal Vss. The discharge circuit N18 is operated according to a voltage level of the sense node SO1, thus discharging the eighth node Node8.

A first transmission circuit TRAN1 is coupled between the third latch L3 of the first page buffer PB1 and the first latch L1 of the second page buffer PB2. The first transmission circuit TRAN1 sends data, stored in the first latch L1 of the second page buffer PB2, to the third latch L3 of the first page buffer PB1.

More particularly, the first transmission circuit TRAN1 includes a nineteenth switching element N19 and a twentieth switching element N20 coupled in series between the ground terminal Vss and the third latch L3 of the first page buffer PB1. The nineteenth switching element N19 is operated in response to a transmission signal TRN and may be formed of an NMOS transistor. The twentieth switching element N20 is operated according to a voltage level of a sense node SO2 of the second page buffer PB2 adjacent to the first page buffer PB1 and may be formed of an NMOS transistor.

The second transmission circuit TRAN2 is coupled between the second page buffer PB2 and a third page buffer (not shown) adjacent to the second page buffer PB2. The second transmission circuit TRAN2 sends data, stored in the first latch (not shown) of the third page buffer (not shown), to the third latch L3 of the second page buffer PB2.

The determination unit DE receives data, stored in the first to third latches L1 to L3, through first to third data lines DL1 to DL3, respectively, and determines the data stored in the first to third latches L1 to L3.

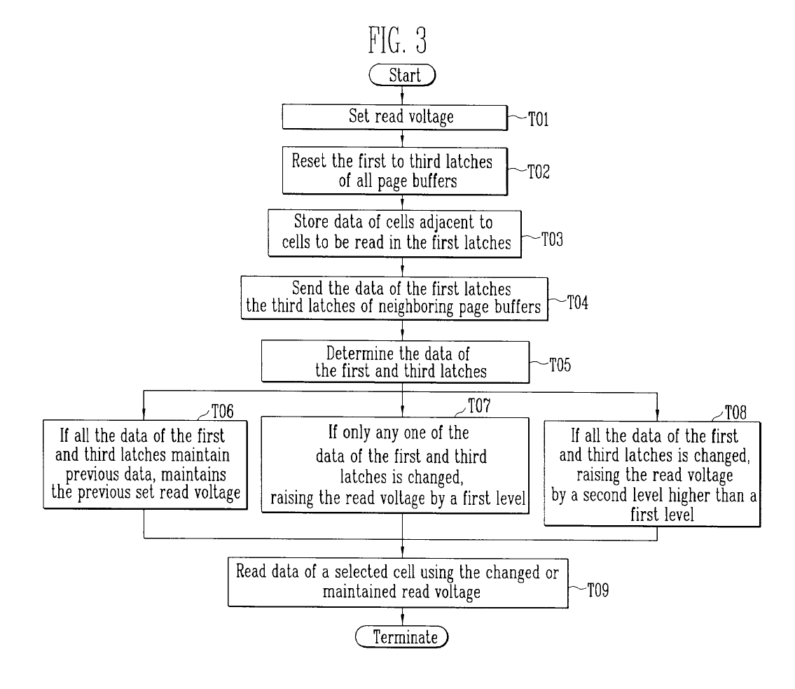

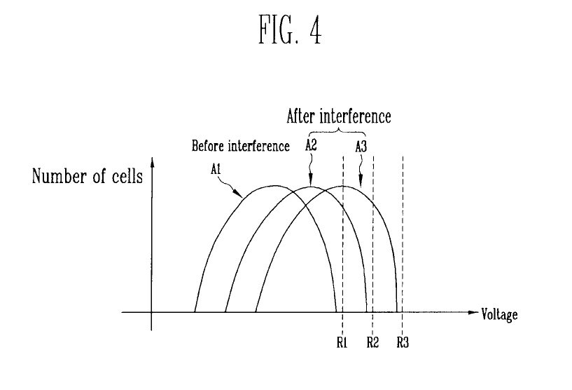

FIG. 3 is a flowchart illustrating a read method of the semiconductor memory device according to an embodiment of the invention, and FIG. 4 is a diagram illustrating read voltage according to a shift of threshold voltages.

Referring to FIGS. 2, 3, and 4, when a read operation is started, a read voltage is set up at step T01. The read voltage may be set by a controller (not shown) of the semiconductor memory device. All the first to third latches L1 to L3 of the page buffers PB1 and PB2 are set at step T02. That is, the reset circuits N21 to N23 are turned on in response to the reset signal RS. Accordingly, a voltage level of the third node Node3 of the first latch L1, the fifth node Node5 of the second latch L2, and the seventh node Node7 of the third latch L3 become a high level. After all the first to third latches L1 to L3 are reset, the reset circuits N21 to N23 are turn off.

Data of cells adjacent to cells Cs that is to be read (that is, data of adjacent first and second cells Cr1 or Cr2) are stored in the first latches L1 at step T03.

More particularly, the precharge circuit P1 is turned on, thereby precharging the sense nodes SO1 and SO2. When the sense nodes SO1 and SO2 are precharged, the discharge circuit N18 is turned on, and so the eighth node Node8 is discharged. When the sense signal PBSENSE and the even select signal BSLe become a high level, the sense circuit N5 and the third switching element N3 are turned on and so the even bit line BLe is precharged. A temporary read voltage is supplied to a selected word line WL1, and a read pass voltage is supplied to the remaining word lines. Here, in case where only whether the first and second cells Cr1 and Cr2, which are adjacent to the cells Cs to be read, have been programmed is checked, the temporary read voltage of 0 V may be supplied. That is, the temporary read voltage and the read pass voltage of 0 V may be supplied. In the state in which the common source line CSL is coupled to the ground terminal Vss, the drain select transistor DST and the source select transistor SST are turned on. A voltage level of the sense node SO may be lowered or maintained according to whether the first or second cell Cr1 or Cr2 has been programmed.

For example, in case where the first cell Cr1 is a programmed cell, a voltage level of the sense node SO1 remains in a high level because a voltage level of the precharged even bit line BLe remains intact. Next, the thirteenth switching element N13 of the first setup circuit DC is turned on. When both the discharge circuit N18 and the thirteenth switching element N13 are turned on, the ground terminal Vss and the third node Node3 of the first latch L1 are coupled together, and so the third node Node3 is changed from a high level to low level. That is, the data stored in the first latch L1 is changed.

In case where the first cell Cr1 is an erase cell (that is, a cell not programmed), a voltage level of the even bit line BLe is lowered because the precharged even bit line BLe is coupled to the common source line CSL. Accordingly, a voltage level of the sense node SO1 is also lowered, and so the discharge circuit N18 is turned off. Next, when the thirteenth switching element N13 of the first setup circuit DC is turned on, the data stored in the first latch L1 still maintains a high level (that is, a previous level) because the discharge circuit N18 remains turned off.

In a similar way, data stored in the first latch L1 of the second page buffer PB2 is changed or maintains previous data according to whether the second cell Cr2 of the third string ST3 has been programmed.

The data stored in the first latches L1 are sent to the third latches L3 of neighboring page buffers at step T04.

That is, initially the data of the first cell Cr1 is stored in the first latch L1 of the first page buffer PB1, and the data of the second cell Cr2 is stored in the first latch L1 of the second page buffer PB2. The data stored in the first latch L1 of the second page buffer PB2 is then sent to the third latch L3 of the first page buffer PB1.

More particularly, in the state in which all the first to third setup circuits DC, DM, and DT are inactivated, the sixth switching element N6 of the first transfer circuit QC is turned on. Accordingly, a voltage level of the sense node SO2 is determined according to a level of voltage supplied to the second node Node2 of the first latch L1.

For example, in case where the second cell Cr2 is a programmed cell, a voltage level of the second node Node2 becomes a high level because a voltage level of the third node Node3 of the second page buffer PB2 is a low level. At this time, when the sixth switching element N6 of the first transfer circuit QC is turned on, a voltage level of the sense node SO2 becomes a high level because the second node Node2 is coupled to the sense node SO2.

When the voltage level of the sense node SO2 becomes a high level, the twentieth switching element N20 of the first transmission circuit TRAN1 is turned on. At this time, the twentieth switching element N20 of the second page buffer PB2 is also operated according to a voltage level of the sense node SO3 of the third page buffer (not shown). Next, when the transmission signal TRN becomes a high level, the nineteenth switching element N19 is turned on, and so the ground terminal Vss and the seventh node Node7 of the third latch L3 of the first page buffer PB1 are coupled together. Accordingly, the seventh node Node7 of the third latch L3 becomes a low level.

Accordingly, the data of the first cell Cr1 and second cell Cr2, adjacent to the cells Cs to be read in different directions, are stored in the first latch L1 and the third latch L3 of each of the page buffers PB1 and PB2.

Whether the first cell Cr1 and second cell Cr2 adjacent to the cells Cs to be read have been programmed is determined on the basis of the data of the first latch L1 and the third latch L3 at step T05. More particularly, the determination unit DE receives the data of the first latch L1 through the first data line DL1 and receives the data of the third latch L3 through the third data line DL3 and determines whether each of the cells has been programmed on the basis of the received data. A criterion for the determination may be based on whether the data of each of the latches has been changed.

If, as a result of the determination, all the data of the first and third latches L1 and L3 are determined to maintain previous data, it corresponds to a case in which both the first and second cells Cr1 and Cr2 adjacent to the cells Cs to be read are not programmed (that is, A1 of FIG. 4), and so the initially set read voltage (R1 of FIG. 4) is maintained at step T06.

If, as a result of the determination at step T05, only the data of one of the first and third latches L1 and L3 is determined to have been changed, it corresponds to a case where only one of the first and second cells Cr1 and Cr2 adjacent to the cells Cs to be read has been programmed (A2 of FIG. 4). Accordingly, the read voltage is raised to a first level (R2) at step T07.

If, as a result of the determination at step T05, all the data of the first and third latches L1 and L3 are determined to have been changed, it corresponds to a case where both the first and second cells Cr1 and Cr2 adjacent to the cells Cs to be read have been programmed (A3 of FIG. 4). Accordingly, the read voltage is raised to a second level higher than the first level (R3 of FIG. 4) at step T08.

A read operation is performed on the cells Cs to be read using the read voltage R1, R2, or R3 which is changed or maintained according to any one of the steps T06, T07, and T08 at step T09. The read operation is performed on the cells Cs to be read using the second latches L2.

As described above, the read voltage of the cells Cs to be read is changed (that is, R1, R2, or R3) according to whether the cells Cr1 and Cr2 adjacent to the cells Cs to be read have been programmed. Accordingly, although a threshold voltage is raised because of interference, valid data can be read.

According to this disclosure, a read operation is performed by changing a read voltage of selected memory cells according to whether neighboring memory cells have been programmed. Accordingly, reliability of data read operation can be improved.

What is claimed is:

1. A read method of a semiconductor memory device, comprising:
reading a first data of a cell adjacent to a cell to be read and storing the first data in a first latch of a first page buffer;
sending the first data to a second latch of a second page buffer adjacent to the first page buffer;
setting a read voltage of the cell to be read according to a value of the first data stored in the first and second latches; and
reading a second data of the cell to be read using the set read voltage.

2. The read method of claim 1, wherein reading the first data is performed using a first of three latches of the first and second page buffers.

3. The read method of claim 1, further comprising resetting the first and second latches before reading the first data.

4. The read method of claim 3, further comprising, after storing the data in the first and second latches:
if one of the data stored in the first and second latches is changed, raising a level of the read voltage by a first level; and
if both data stored in the first and second latches is changed, raising the level of the read voltage by a second level higher than the first level.

5. A semiconductor memory device, comprising:
page buffers, each allocated to a pair of bit lines, comprising first, second, and third latches;
transmission circuits coupled between adjacent page buffers; and
a determination unit configured to determine whether read cells are in a program state or an erase state according to the data stored in the first, second, and third latches.

6. The semiconductor memory device of claim 5, wherein each of the transmission circuits is configured to effectively transmit data from the first latch of a subsequent adjacent page buffer to the third latch of a present adjacent page buffer, in response to a transmission signal.

7. The semiconductor memory device of claim 6, wherein the transmission circuits are coupled in series between the third latch and the ground terminal and configured to comprise a switching element operated in response to the transmission signal and a switching element operated in response to the data of the first latch.

8. The semiconductor memory device of claim 7, wherein the switching elements are formed of NMOS transistors.

9. The semiconductor memory device of claim 5, wherein the determination unit determines that corresponding cells have been programmed if the data of the first and third latches shift from a high level to a low level.

10. The semiconductor memory device of claim 5, wherein the determination unit determines whether neighboring cells have been programmed on the basis of the data stored in the first to third latches.

11. A semiconductor memory device, comprising:
first to fourth strings;
first to fourth bit lines respectively coupled to the first to fourth strings;
a first bit line selection unit configured to select any one of the first and second bit lines;
a second bit line selection unit configured to select any one of the third and fourth bit lines;
first and second page buffers each configured to comprise first, second, and third latches and to store read data of a memory cell in a latch of any one of the first to third latches through the selected bit line;
a transmission circuit configured to send the data of the first latch of the second page buffer to the third latch of the first page buffer; and
a determination unit configured to determine whether read cells have been programmed on the basis of the data stored in the first to third latches of each of the first and second page buffers.

12. The semiconductor memory device of claim 11, wherein the determination unit determines the data of each of the first to third latches.
